(19) United States
(12) Patent Application Publication
(10) Pub. No.: US 2012/0235244 A1
(43) Pub. Date: Sep. 20, 2012

(54) Semiconductor Structure and Method for Manufacturing the Same

(75) Inventors: Haizhou Yin, Poughkeepsie, NY (US); Zhijiong Luo, Poughkeepsie, NY (US); Huilong Zhu, Poughkeepsie, NY (US)

(73) Assignee: INSTITUTE OF MICROELECTRONICS, CHINESE ACADEMY OF SCIENCES, Beijimg (CN)

(21) Appl. No.: 13/380,482

(22) PCT Filed: Apr. 18, 2011
(86) PCT No.: PCT/CN11/72945

§ 371 Date: Dec. 22, 2011

(30) Foreign Application Priority Data
Mar. 18, 2011 (CN) 201110066929.0
Apr. 18, 2011 (CN) PCT/CN2011/072945

(51) Int. Cl. H01L 27/088; H01L 29/772; H01L 21/336

(52) U.S. Cl. 257/368; 438/299; 257/288; 257/E21.409; 257/E27.06; 257/E29.242

(57) ABSTRACT

A method for manufacturing a semiconductor structure comprises: providing a substrate, forming an active region on the substrate, forming a gate stack or a dummy gate stack on the active region, forming a source extension region and a drain extension region at opposite sides of the gate stack or dummy gate stack, forming a spacer on sidewalls of the gate stack or dummy gate stack, and forming a source and a drain on portions of the active region exposed by the spacer and the gate stack or dummy gate stack; removing at least a part of a source-side portion of the spacer, such that the source-side portion of the spacer has a thickness less than that of a drain-side portion of the spacer; and forming a contact layer on portions of the active region exposed by the spacer and the gate stack or dummy gate stack. Correspondingly, the present invention further provides a semiconductor structure. The present invention is beneficial to the reduction of the contact resistance of the source extension region and meanwhile can also reduce the parasitic capacitance between the gate and the drain extension region.

This application claims priority to a Chinese Patent Application No. 201110066929.0, filed on Mar. 18, 2011 and entitled “SEMICONDUCTOR STRUCTURE AND METHOD FOR MANUFACTURING THE SAME”, which is hereby incorporated by reference in its entirety.

### FIELD OF THE INVENTION

The present invention relates to the semiconductor manufacturing technology, and particularly to a semiconductor structure and a method for manufacturing the same.

### BACKGROUND OF THE INVENTION

A metal-oxide-semiconductor field-effect transistor (MOSFET) is a transistor that can be widely used in digital circuits and analog circuits. With continuous reduction in a size of the semiconductor structure, a length of a channel beneath a gate decreases correspondingly, thereby causing occurrence of short channel effects. A common means for reducing short channel effects is to form a source extension region and a drain extension region with a shallow depth.

In order to improve the performance of the semiconductor structure, it is necessary to reduce not only a contact resistance of a source and a drain, but also a contact resistance of a source extension region and a drain extension region as well as a parasitic capacitance between the source extension region, the drain extension region and a gate. With respect to the contact resistance of the drain extension region, the contact resistance of the source extension region has a relatively significant influence on the performance of the semiconductor structure in its size. Due to Miller Effect, with respect to the parasitic capacitance between the source extension region and the gate, the parasitic capacitance between the drain extension region and the gate has a relatively significant influence on the performance of the semiconductor structure in its size. That is to say, it is desired to reduce the contact resistance of the source extension region more in reducing the contact resistances of the source extension region and the drain extension region; whereas it is desired to reduce the parasitic capacitance between the drain extension region and the gate more in reducing the parasitic capacitances between the drain extension region, the drain extension region and the gate.

Therefore, it is a problem urgently to be solved to strike a balance between the reduction in the contact resistance of the source extension region and that in the parasitic capacitance between the gate and the drain extension region in the semiconductor structure.

### SUMMARY OF THE INVENTION

The object of the invention is to provide a semiconductor structure and a method for manufacturing the same, which are beneficial to striking a balance between the reduction in the contact resistance of the source extension region and that in the parasitic capacitance between the gate and the drain extension region in the semiconductor structure.

According to one aspect of the invention, there provides a method for manufacturing a semiconductor structure, comprising:

providing a substrate, forming an active region on the substrate, forming a gate stack or a dummy gate stack on the active region, forming a source extension region and a drain extension region at opposite sides of the gate stack or dummy gate stack, forming a spacer on sidewalls of the gate stack or dummy gate stack, and forming a source and a drain on portions of the active region exposed by the spacer and the gate stack or dummy gate stack;

removing at least a part of a source-side portion of the spacer, such that the source-side portion of the spacer has a thickness less than that of a drain-side portion of the spacer; and

forming a contact layer on portions of the active region exposed by the spacer and the gate stack or dummy gate stack.

A first contact layer is formed on the source and an exposed region of the source extension region, and a second contact layer that is not symmetrical with the first contact layer is formed on at least a part of the drain.

Another aspect of the invention further provides a semiconductor structure, comprising:

at least two adjacent gate stacks or dummy gate stacks positioned on an active region, source-side portions and drain-side portions of spacers, the source-side portions and the drain-side portions of the spacers are positioned on sidewalls of the gate stack or dummy gate stack, wherein:

for each of the gate stacks or dummy gate stacks, the source-side portion has a thickness less than that of the drain-side portion of the spacer;

a contact layer is formed at an upper surface of portions of the active region exposed by the source-side portion and the drain-side portion as well as the gate stack or dummy gate stack.

According to another aspect of the present invention, there further provides a method for manufacturing a semiconductor structure, comprising:

providing a substrate, forming an active region on the substrate, forming a gate stack or a dummy gate stack on the active region, forming a source extension region and a drain extension region at opposite sides of the gate stack or dummy gate stack, forming a spacer on sidewalls of the gate stack or dummy gate stack, and forming a source and a drain on portions of the active region exposed by the spacer and the gate stack or dummy gate stack;

forming a first contact layer on an upper surface of a portion of the active region at the source side;

forming an interlayer dielectric layer to cover the substrate;

etching the interlayer dielectric layer to form a contact hole which at least exposes a part of a portion of the active region at the drain side;

forming a second contact layer on the part of the portion of the active region at the drain side.

According to another aspect of the present invention, there further provides a semiconductor structure, comprising a gate stack, a source, a drain and a contact plug, wherein the gate stack is positioned on an active region, the source and the drain are respectively positioned in the active region at opposite sides of the gate stack, and the contact plug is connected to portions of the active region exposed by the gate stack, wherein:

a first contact layer is formed on an upper surface of a portion of the active region at the source side; and

a second contact layer is formed at least between the portion of the active region at the drain side and the contact plug.

Compared with the prior art, the present invention has the following advantages.

By removing at least a part of the source-side portion of the spacer, the thickness of the source-side portion is less than that of the drain-side portion. The formation of the contact layer on portions of the active region exposed by the spacer and the gate stack or dummy gate stack makes the contact layer at the source side closer to the gate stack than that at the drain side. Compared with the semiconductor structure with the same thickness of the source-side portion, the distance between the contact layer at the drain side and the gate stack is larger, which is beneficial to the reduction of the parasitic capacitance between the drain extension region and the gate; compared with the semiconductor structure with the same thickness of the drain-side portion, the distance between the contact layer at the source side and the gate stack is smaller, which is beneficial to the reduction of the contact resistance of the source extension region.

By forming the first contact layer on the upper surface of the active region at the source side, and then etching the interlayer dielectric layer to form a contact hole (conductive metal is filled in the contact hole to form the contact plug) after the formation of the interlayer dielectric layer, the contact hole at least exposes a part of a portion of the active region at the drain side. The formation of the second contact layer on part of the active region makes the first contact layer closer to the gate stack than the second contact layer under the precondition that the thicknesses of the source-side portion and the drain-side portion are the same, so as to possibly make the distance between the second contact layer and the gate stack larger, which is beneficial to the reduction of the parasitic capacitance between the drain extension region and the gate.

Further, by symmetrically removing at least one part of the spacer, the distance between the first contact layer and the gate stack is smaller, which is beneficial to the reduction of the contact resistance.

### BRIEF DESCRIPTION OF THE DRAWINGS

Additional features, objects and advantages of the present invention will become more apparent by reading the detailed descriptions on the non-limited embodiments made with reference to the following drawings.

FIG. 1 is a flow chart of a method for manufacturing a semiconductor structure according to one embodiment of the present invention;

FIGS. 2(a) to 2(k) are cross-sectional schematic diagrams of each of the stages for manufacturing the semiconductor structure in accordance with the flow shown in FIG. 1 according to one embodiment of the present invention;

FIG. 3 shows a flow chart of a method for manufacturing a semiconductor structure according to another embodiment of the present invention;

FIGS. 3(a) to 3(j) are cross-sectional schematic diagrams of part of the stages for manufacturing the semiconductor structure in accordance with the flow shown in FIG. 3 according to another embodiment of the present invention; and

FIG. 4(a) shows a resistance of a nickel-silicide formed by depositing a Ni layer with different thicknesses at different temperatures; and

FIG. 4(b) shows a resistance of a nickel platinum-silicide formed by depositing a NiPt layer with different thicknesses and components at different temperatures.

### DETAILED DESCRIPTION OF THE EMBODIMENTS

The embodiments of the present invention are described in detail as follows, the examples of which are shown in the drawings. The embodiments described as follows in reference to the drawings are exemplary and merely used to interpret the present invention, instead of restricting the present invention.

The following disclosure provides many different embodiments or examples for implementing different structures of the present invention. In order to simplify the disclosure of the present invention, the components and arrangement of specific examples are described in the following text. Apparently, they are just exemplary, and do not intend to restrict the present invention. In addition, reference numbers and/or letters can be repeatedly used in different examples of the present invention for the purposes of simplification and clearness, without indicating the relationships between the discussed embodiments and/or arrangements. Furthermore, the present invention provides examples of various specific processes and materials, but a person skilled in the art can realize the availability of other processes and/or usage of other materials. To be noted, the components as shown in the drawings are not always drawn on the scale. In the present invention, the descriptions on the known assemblies as well as treatment technologies and processes are omitted, so as to avoid any unnecessary restriction to the present invention.

As stated above, in the conventional process of forming the contact layer to reduce the contact resistance, the contact layer is symmetrically formed over the source/drain region. Since the closer the contact layer is to the gate, the smaller the contact resistance is and the bigger the parasitic capacitance is, the reduction of the contact resistance is in opposition to that of the parasitic capacitance. In order to reduce the influence of the Miller Effects, it is necessary to specially design and consider the contact layer on the source/drain region.

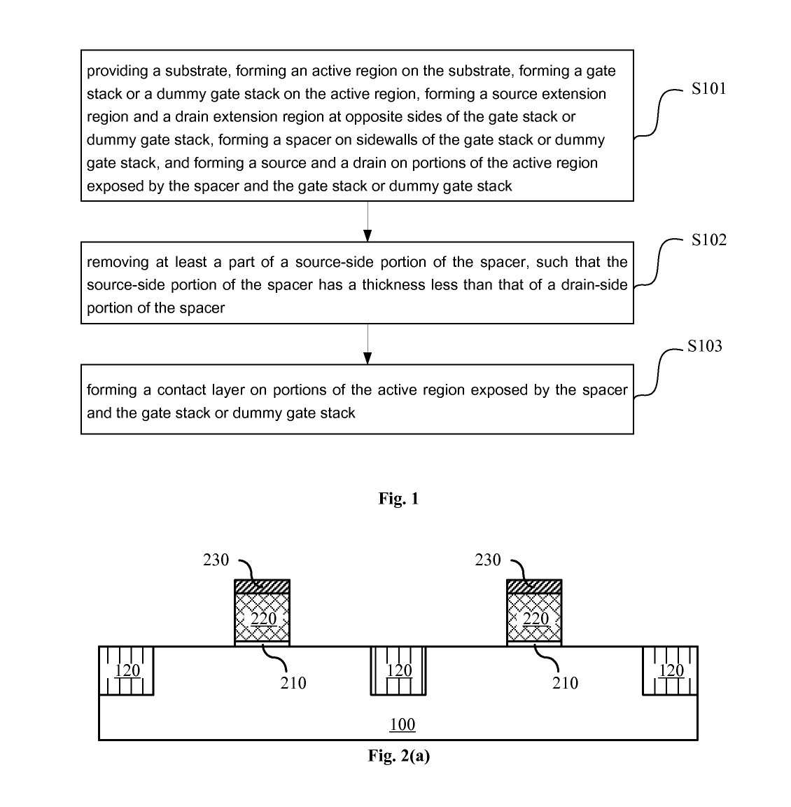

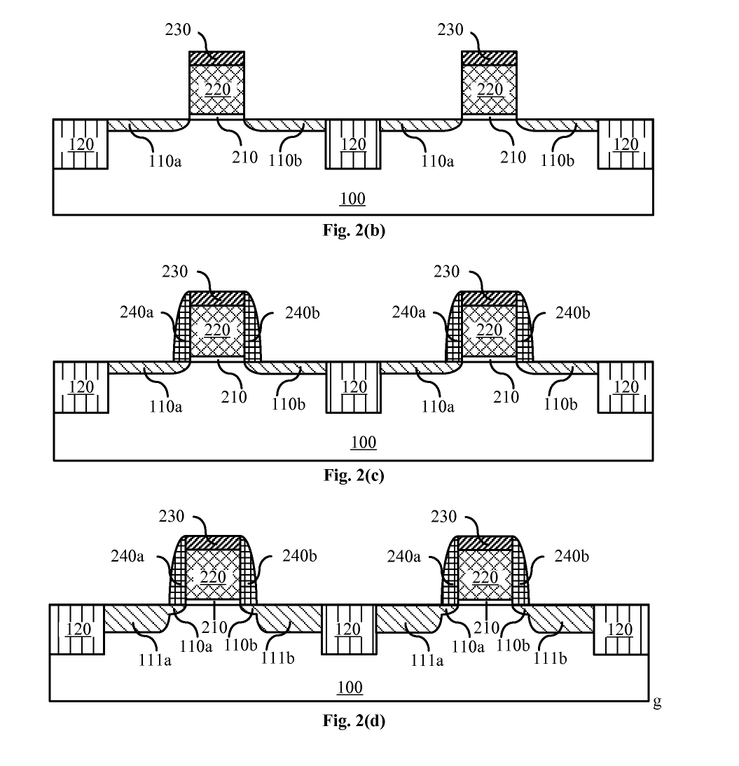

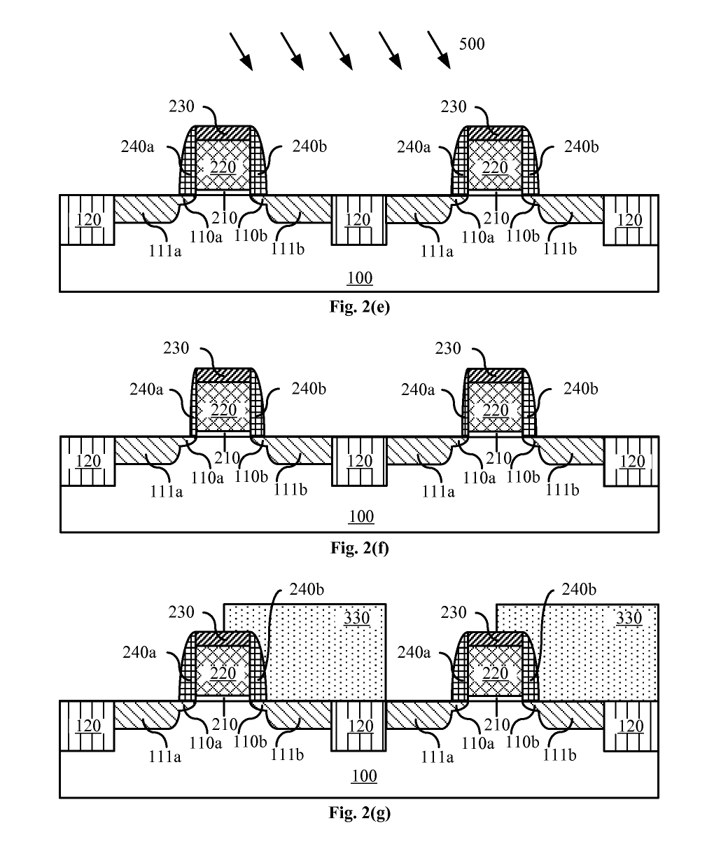

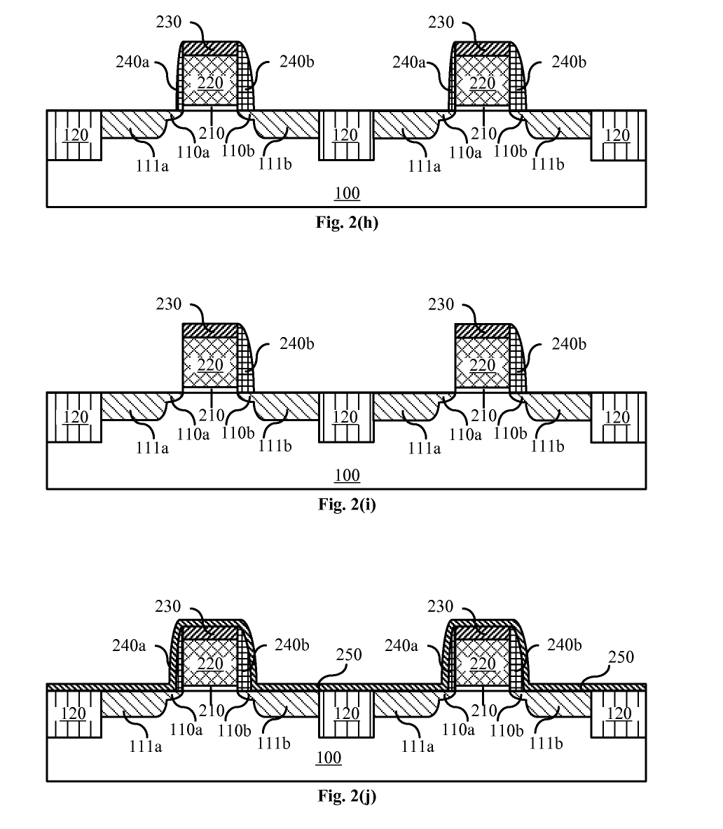

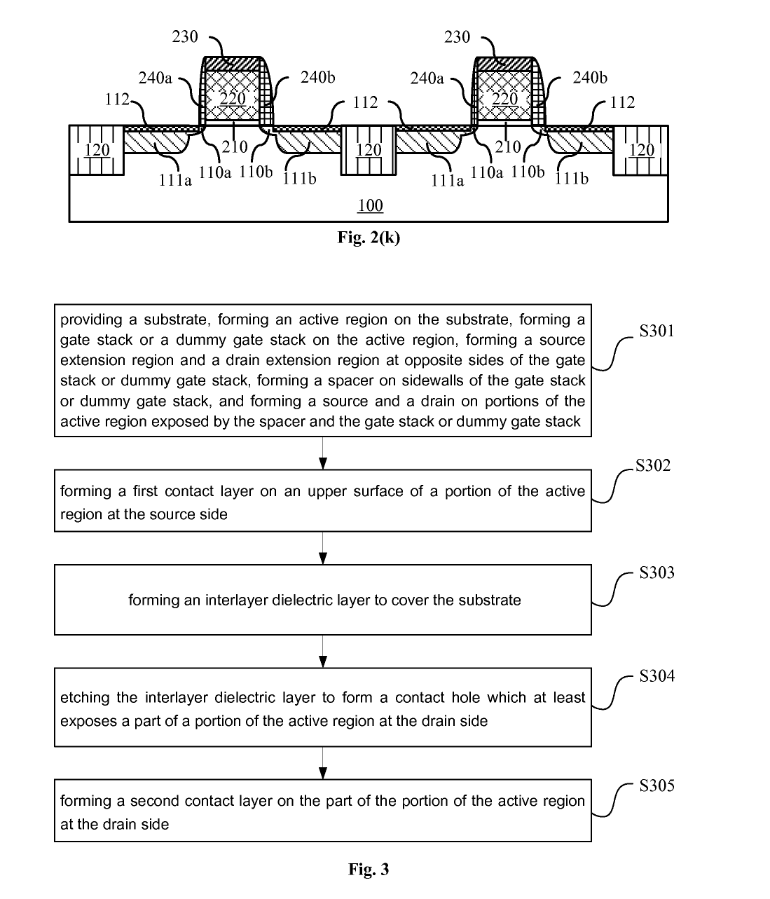

According to one aspect of the present invention, there provides a method for manufacturing a semiconductor structure, as shown in FIG. 1. In the following, the method for forming a semiconductor structure in FIG. 1 is described in detail through one embodiment of the present invention in combination with FIGS. 2(a) to 2(k).

To be noted, the method of the present invention can be used for a gate first process and a gate last process. In the gate first process, the gate stack is formed at first, whereas in the gate last process, a replacement gate process is performed after the dummy gate stack is formed, so as to form the gate stack. The situation of the dummy gate stack mentioned in the following is the method for implementing the present invention in the gate last process.

Referring to FIG. 1 and FIGS. 2(a) to 2(d), in step S101, the substrate 100 is provided, on which an active region is formed, a gate stack or a dummy gate stack is formed on the active region, a source extension region 110a and a drain extension region 110b are formed at opposite sides of the gate stack or dummy gate stack, a spacer is formed on sidewalls of the gate stack or dummy gate stack, and a source 111a and a drain 111b are formed at portions of the active region exposed by the spacer and the gate stack or dummy gate stack.

In the present embodiment, the substrate 100 comprises a silicon substrate (for example, a silicon wafer). According to the design requirement known in the prior art (for example, a P-type substrate or N-type substrate), the substrate 100 can comprise various doped configurations. In other embodiments, the substrate 100 may further comprise other basic semiconductors (for example, III-V group materials), such as germanium. Or, the substrate 100 may comprise a compound semiconductor, such as silicon carbide, gallium arsenide or indium arsenide. Typically, the substrate 100 can have, but not limited to, a thickness of about several hundreds of micrometers, for example, within the thickness range of about 400 μm-800 μm.

An isolation region, for example, a shallow trench isolation (STI) structure 120, can be formed in the substrate 100 so as to electrically isolate continuous field effect transistors.

Before forming the gate stack or dummy gate stack, an active region (not shown in the drawings) is formed on the substrate 100, and the active region is a substrate region for manufacturing a semiconductor structure, formed through doping.

Referring to FIG. 2(a), when a gate stack or a dummy gate stack is formed, a gate dielectric layer 210 is formed on the active region firstly. In the present embodiment, the gate dielectric layer 210 can be formed of silicon oxide, silicon nitride and a combination thereof. In other embodiments, the gate dielectric layer 210 can be formed of a high K dielectric, such as one or more materials selected from a group consisting of HfO₂, HfSiO, HfSiON, HfTaO, HfTiO, HfZrO, Al₂O₃, La₂O₃, ZrO₂, and LaAlO, with a thickness of about 2-10 nm. Afterwards, a gate or a dummy gate 220 is formed by depositing such as polycrystalline silicon, polycrystalline SiGe, noncrystalline silicon and/or metal, on the gate dielectric layer 210, wherein the dummy gate 220 can be doped or non-doped silicon oxide, silicon nitride, silicon oxynitride and/or silicon carbide, with a thickness of about 10-80 nm. Finally, a cap layer 230 is formed on the gate or dummy gate 220, for example, by depositing silicon nitride, silicon oxide, silicon oxynitride, silicon carbide and combinations thereof, for protecting a top region of the gate or dummy gate 220, and preventing the top region of the gate or dummy gate 220 from reacting with the deposited metal layer in the subsequent process of forming the metal silicide layer. According to another embodiment, in the gate last process, the dummy gate stack may also not have the gate dielectric layer 210, and the gate dielectric layer is formed after the dummy gate stack is removed in the subsequent replacement gate process.

Referring to FIG. 2(b), after the gate stack or dummy gate stack is formed, firstly, a relatively shallow source extension region 110a and drain extension region 110b is formed in the substrate 100 in a way of low energy implantation. It is possible to implant P-type or N-type dopants or impurities into the substrate 100. For example, for the PMOS, the source extension region 110a and the drain extension region 110b can be the P-type doped SiGe; for the NMOS, the source extension region 110a and the drain extension region 110b can be the N-type doped Si. Next, the semiconductor structure is subjected to annealing, so as to activate the doping in the source extension region 110a and the drain extension region 110b. The annealing can be formed by adopting appropriate methods including flash annealing and peak annealing. Since a thickness of the source extension region 110a and the drain extension region 110b is relatively small, it is possible to effectively suppress short channel effects. Optionally, the source extension region 110a and the drain extension region 110b can be formed after the formation of the source 111a and the drain 111b.

Referring to FIG. 2(c), next, a spacer is formed on the sidewalls of the gate stack or dummy gate stack, for isolating the gate stack or dummy gate stack. The spacer comprises a source-side portion 240a and a drain-side portion 240b. The source-side portion 240a and the drain-side portion 240b of the spacer can be formed by silicon nitride, silicon oxide, silicon oxynitride, silicon carbide and combinations thereof, and/or other appropriate materials. The source-side portion 240a and the drain-side portion 240b of the spacer may have a multilayer structure (materials of adjacent layers may be different). The source-side portion 240a and the drain-side portion 240b of the spacer may be formed by the processes including depositing and etching, with a thickness range of about 10 nm-100 nm, such as 30 nm, 50 nm or 80 nm.

Referring to FIG. 2(d), subsequently, the source-side portion 240a and the drain-side portion 240b of the spacer are taken as a mask, and the P-type or N-type dopants or impurities are implanted into the substrate 100, so as to form the source 111a and the drain 111b at the opposite sides of the gate stack or dummy gate stack. For example, for the PMOS, the source 111a and the drain 111b can be the P-type doped SiGe; for the NMOS, the source 111a and the drain 111b can be the N-type doped Si. The energy implanted to form the source 111a and the drain 111b is larger than that implanted to form the source extension region 110a and the drain extension region 110b; therefore, the formed source 111a and the drain 111b have a thickness greater than the source extension region 110a and the drain extension region 110b do, and present a scalariform contour with the source extension region 110a and the drain extension region 110b. Afterwards, the semiconductor structure is subjected to annealing, so as to activate the doping in the source 111a and the drain 111b. The annealing can be formed by adopting appropriate methods including flash annealing and peak annealing. In other embodiments, it is also possible to form the source/drain region by taking the spacer and the cap layer 230 as the mask after the formation of the spacer, forming a groove in the active region and then filling a semiconductor material (such as SiGe or Si) inside the groove.

With reference to FIGS. 1, 2(e) to 2(i), in step S102, at least a part of the source-side portion 240a of the spacer is removed, such that the source-side portion 240a of the spacer has a thickness less than that of a drain-side portion 240b of the spacer.

Referring to FIG. 2(e), by obliquely applying a first ion beam (as indicated by arrow 500) on the source 111a side, the reactive ion beam etching is performed on the source-side portion 240a and the drain-side portion 240b of the spacer. Since the ion beam is incident from the position close to the source 111a, and the incident direction has a certain angle (the included angle in a clockwise direction between the first ion beam and a normal line of the substrate is larger than 0° and less than or equal to 90°), the etching degree of the incident ion beam to the source-side portion 240a and the drain-side portion 240b of the spacer is different, so that the thickness of the etched source-side portion 240a is less than that of the drain-side portion 240b of the spacer, by referring to FIG. 2(f). The thickness of the source-side portion 240a and the drain-side portion 240b of the spacer after etching may be determined by controlling the angle of the incident ion beam, the size of the energy of the ion beam, the etching time, and the like. After the reactive ion etching is over, part of the source-side portion 240a of the spacer and part of the drain-side portion 240b of the spacer are etched, so as to correspondingly expose part of the source extension region 110a and part of the drain extension region 110b. Since the thickness of the etched source-side portion 240a of the spacer is less than that of the drain-side portion 240b of the spacer, the exposed region of the source extension region 110a is larger than that of the drain extension region 110b.

Preferably, before the reactive ion beam etching is performed on the source-side portion 240a and the drain-side portion 240b of the spacer, it is possible to obliquely apply a second ion beam to the source-side portion 240a and the drain-side portion 240b of the spacer at the source 111a side (the included angle in a clockwise direction between the second ion beam and a normal line of the substrate is larger than 0° and less than or equal to 90°). An implanted ion and a composition element of a material of the spacer may be in the same clan. For example, when the spacer material is SiN, the implanted ion may be Ge ion, such that the source-side portion 240a and the drain-side portion 240b of the spacer are damaged to some extent. The damaged source-side portion 240a and the drain-side portion 240b of the spacer are etched more easily in the subsequent step of reactive ion beam etching.

Preferably, it is possible to only etch the source-side portion 240a of the spacer at the source 111a side, to expose part or all of the source extension region 110a. Specifically, as shown in FIG. 2(g), firstly, a protection layer 330 is formed at the drain 111b side, and the protection layer 330 may be a hard mask layer so as to cover the drain 111b and the drain-side portion 240b of the spacer. Secondly, as shown in FIGS. 2(h) and 2(i), the processes including wet etching and/or dry etching can be used to remove part or all of the source-side portion 240a of the spacer (at this time, preferably, a material of the cap layer 230 is different from the spacer material, so as to make as small damage to the cap layer 230 as possible when the source-side portion 240a of the spacer is removed) to expose part or all of the source extension region 110a below the source-side portion 240a of the spacer. The wet etching process uses tetramethylammonium hydroxide (TMAH), potassium hydroxide (KOH), or other solutions suitable for etching. The dry etching process uses sulfur hexafluoride (SF₆), hydrogen bromide (HBr), hydrogen iodide (HI), chlorine, argon, helium, hydrides of carbon such as methane (and methyl chloride), acethlene, ethylene and combinations thereof, and/or other appropriate materials. After etching, the protection layer 330 that is not reacted is removed.

In the gate last process, if the material of dummy gate 220 adopts Si or metal, in order to avoid difficult separation of the metal for forming the contact layer (for the Si-containing substrate, the metal silicide layer is formed. In the following, the description is made by taking the Si-containing substrate as an example, the contact layer being called as the metal silicide layer) from the metal as the dummy gate in the subsequent process and the influence of the size of the dummy gate stack, so as to influence a size of the structure of the gate formed after execution of the replacement gate process, it is not appropriate to remove all of the source-side portion 240 of the spacer. If the dummy gate 220 adopts a material that will not react with the deposited metal layer and it is possible to selectively remove the metal layer, it is possible to remove all of the source-side portion 240a of the spacer, so as to enlarge the region where the source extension region 110a reacts with the deposited metal to the greatest extent, thereby reducing the contact resistance between the source extension region 110a and the metal silicide layer.

By referring to FIGS. 1, 2(j) and 2(k), in step S103, a contact layer 112 is formed on portions of the active region exposed by the spacer and the gate stack or dummy gate stack.

A thin metal layer 250 is deposited to cover the substrate 100, the gate stack or dummy gate stack, the source-side portion 240a and the drain-side portion 240b of the spacer, with reference to FIG. 2(j). Afterwards, the annealing operation is performed, so that the metal layer 250 reacts with the active regions at the opposite sides of the source-side portion 240a and the drain-side portion 240b of the spacer. For the situation where both the source-side portion 240a and the drain-side portion 240b of the spacer are etched, a thin metal silicide layer 112 is formed on upper surfaces of the source 111a, the exposed region of the source extension region 110a, the drain 111b and the exposed region of the drain extension region 110b after annealing, with reference to FIG. 2(k). In another embodiment, for the situation where only the source-side portion 240a of the spacer is etched, a thin metal silicide layer 112 is formed on upper surfaces of the source 111a, the exposed region of the source extension region 110a and the drain 111b after annealing. Since the thickness of the source-side portion 240a of the spacer is less than that of the drain-side portion 240b of the spacer, that is, the area of the exposed region of the source extension region 110a is larger than that of the exposed region of the drain extension region 110b, the metal silicide layers 112 formed at the opposite sides of the gate stack or dummy gate stack are not symmetrical, wherein a distance between the metal silicide layer 112 at the side of the source-side portion 240a of the spacer and the gate stack or dummy gate stack is less than that between the metal silicide layer 112 at the side of the drain-side portion 240b of the spacer and the gate stack or dummy gate stack. By selecting a thickness and a material of the deposited metal layer 250, it is possible to make the formed metal silicide layer 112 still have thermal stability at a high temperature (such as 850° C.), to maintain a relatively low resistance and to be beneficial to the reduction of the increase of the resistance of the metal silicide layer 112 caused by high temperature annealing in the subsequent semiconductor structure manufacturing process. A material of the metal layer 250 comprises one of Co, Ni and NiPt or any combination thereof.

If the material of the metal layer 250 is Co, the thickness of the metal layer 250 formed by Co is less than 5 nm.

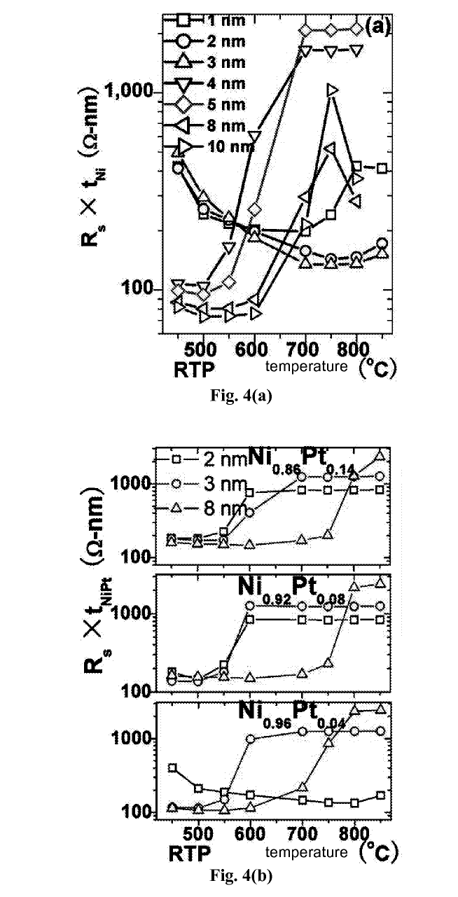

If the material of the metal layer 250 is Ni, with reference to FIG. 4(a), the thickness of the metal layer 250 formed by Ni is less than 4 nm, preferably 2-3 nm. FIG. 4(a) shows a resistance of a nickel-silicide formed by depositing the Ni layer with different thicknesses at different temperatures, the horizontal coordinates representing a temperature at which a rapid thermal processing (PRT) is performed, and the vertical coordinates representing the resistance of the nickel-silicide. Different curves represent the deposited Ni layer with different thicknesses when the nickel-silicide is formed. It can be seen from FIG. 4(a) that when the temperature of the rapid thermal processing is higher than 700° C., a thickness of the deposited metal Ni layer is about 2-3 nm and the resistance of the formed nickel-silicide is relatively low. When the material of the metal layer 250 is Ni, the thickness of the formed metal silicide 112 is about twice of that of the metal layer 250, for example, when the thickness of the deposited Ni layer is 4 nm, the thickness of the formed NiSi is about 8 nm.

If the material of the metal layer 250 is NiPt, with reference to FIG. 4(b), the thickness of the metal layer 250 formed by NiPt is less than 3 nm, and a content of Pt in the NiPt is less than 5%. FIG. 4(b) shows a resistance of the nickel platinum-silicide formed by depositing the NiPt layer with different thicknesses at different temperatures, composed of the upper, middle and lower graphs, the horizontal coordinates representing a temperature at which the rapid thermal processing is performed, and the vertical coordinates representing the resistance of the nickel platinum-silicide. Different curves in the upper graph represent the NiPt layers with different thicknesses when the metal layer 250 is NiPt, the content of Ni is 86% and the content of Pt is 14%. Different curves in the middle graph represent the NiPt layers with different thicknesses when the metal layer 250 is NiPt, the content of Ni is 92% and the content of Pt is 8%. Different curves in the lower graph represent the NiPt layer with different thicknesses when the metal layer 250 is NiPt, the content of Ni is 96% and the content of Pt is 4%. It can be seen from FIG. 4(b) that the resistance of the formed nickel platinum-silicide is relatively low, that is, the thermal stability is relatively good under the circumstance where the content of Pt in the deposited NiPt layer is 4% and the thickness of the NiPt layer is 2 nm when the temperature of the rapid thermal processing is higher than 700° C. Therefore, if the material of the metal layer 250 is NiPt, the thickness of the metal layer 250 formed by NiPt is less than 3 nm; preferably, the content of Pt in NiPt is less than 5%.

After the metal layer 250 is deposited, the semiconductor structure is annealed. After annealing, the metal silicide layer 112 formed at the opposite sides of the gate stack or dummy gate stack comprises one or more materials selected from a group consisting of CoSi₂, NiSi and Ni(Pt)Si_{2-y}, with the thickness less than 10 nm. Finally, the residual metal layer 250 which is un-reacted is removed by means of selective etching

Subsequently, the manufacture of the semiconductor structure is completed according to the steps of the conventional semiconductor manufacturing process. For example, an interlayer dielectric layer is deposited on the substrate of the semiconductor structure; and then the replacement gate process is performed, and the high K gate dielectric layer is subjected to annealing; and the interlayer dielectric layer is etched to form a contact hole, and a contact metal is filled in the contact hole to form a contact plug. Since the above conventional manufacturing processes are publicly known for persons skilled in the art, it is unnecessary to give more details.

After the above step is completed, in the semiconductor structure, a thin metal silicide layer 112 that is not symmetrical is formed on the active region at the opposite sides of the source-side portion 240a and the drain-side portion 240b of the spacer, wherein the metal silicide layer 112 formed on upper surfaces of the source 111a and at least a part of the source extension region 110a may reduce the contact resistance of the source 111a and the source extension region 110a, whereas the distance between the metal silicide layer 112 formed on an upper surface of the drain 111b, or upper surfaces of the drain 111b and part of the drain extension region 110b and the gate stack or dummy gate stack is larger than that between the silicide metal layer 112 at the side of the source-side portion 240a of the spacer and the gate stack or dummy gate stack, so that compared with the semiconductor structure with the same thickness of the source-side portion of the spacer, the parasitic capacitance between the gate stack or dummy gate stack and the drain extension region 110b can be reduced, which is beneficial to the improvement of the semiconductor structure. In addition, when the metal silicide layer 112 comprises one or more materials selected from a group consisting of CoSi₂, NiSi and Ni(Pt)Si_{2-y} and has a thickness less than 10 nm, the metal silicide layer 112 can still have thermal stability and maintain a relatively low resistance at an annealing temperature (for example, 700° C.-800° C.) at which the dummy gate stack is removed and the gate stack is formed subsequently.

Correspondingly, according to the method for manufacturing a semiconductor structure, the present invention further provides a semiconductor structure that is explained below according to FIG. 2(k). FIG. 2(k) shows the finally formed semiconductor structure after the steps shown in FIG. 1 are performed according to one embodiment of the present invention.

As shown in FIG. 2(k), in the present embodiment, the semiconductor structure comprises: a substrate 100, at least two adjacent gate stacks or dummy gate stacks positioned on the active region, sources 111a, drains 111b, source extension regions 110a, drain extension regions 110b, source-side portions 240a and drain-side portions 240b of spacers, wherein the sources 111a, the drains 111b, the source extension regions 110a and the drain extension regions 110b are formed in the substrate 100; the thickness of the source extension regions 110a is less than that of the sources 111a, and the thickness of the drain extension regions 110b is less than that of the drains 111b. The source extension regions 110a and the drain extension regions 110b present a scalariform contour with the sources 111a and the drains 111b.

The source-side portions 240a and the drain-side portions 240b of the spacers are positioned on sidewalls of the gate stacks or dummy gate stacks. For each of the gate stacks or dummy gate stacks, the source-side portion 240a positioned on the sidewall thereof has a thickness less than that of the drain-side portion 240b of the spacer.

The metal silicide layers 112 that are asymmetrical are formed on the upper surface of the active region at the opposite sides of the source-side portions 240a and the drain-side portions 240b of the spacers. That is, the distance between the metal silicide layer 112 at the side of the source-side portion 240a of each of the spacers and the respective gate stack or dummy gate stack is less than that between the silicide metal layer 112 at the side of the drain-side portion 240b of each of the spacers and the respective gate stack or dummy gate stack. The metal silicide layer 112 formed on the upper surfaces of the sources 111a and part of the source extension regions 110a is beneficial to the reduction of the contact resistance of the sources 111a and the source extension regions 110a; the metal silicide layer 112 formed on upper surface of the active region at the side of the drain-side portions 240b of the spacers can reduce the parasitic capacitance between the gate stacks or dummy gate stacks and the drain extension regions 110b due to a larger distance away from the gate stacks or dummy gate stacks, which is beneficial to the reduction of the Miller Effects and the improvement of the performance of the semiconductor structure.

The metal silicide layer 112 comprises one or more materials selected from a group consisting of CoSi₂, NiSi and Ni(Pt)Si_{2-y}, and the thickness of the metal silicide layer 112 is less than 10 nm. Since the metal silicide layer 112 has thermal stability, and can maintain a relatively low resistance at a high temperature up to 850° C., the metal silicide layer 112 can still have thermal stability and maintain a relatively low resistance at an annealing temperature (for example, 700° C.-800° C.) at which the dummy gate stack is removed and the gate stack is formed subsequently.

Preferably, the dummy gate 220 can be formed by adopting the material which does not react with the deposited metal layer 250. The material comprises, but not limited to, oxide, nitride and any combination thereof. Under this circumstance, the dummy gate 220 is not necessarily protected specially. Therefore, it is possible to remove all of the source-side portion 240a of the spacer, so as to expose the source extension region 110a to the greatest extent, and to enlarge the region where the source extension region 110a reacts with the metal layer 250, thereby further reducing the contact resistance of the source extension region 110a.

The structure compositions, materials and formation methods of each of the parts in each embodiment of the semiconductor structure can be the same as what are described in the formation method embodiment of said semiconductor structure described before, without repeated descriptions herein.

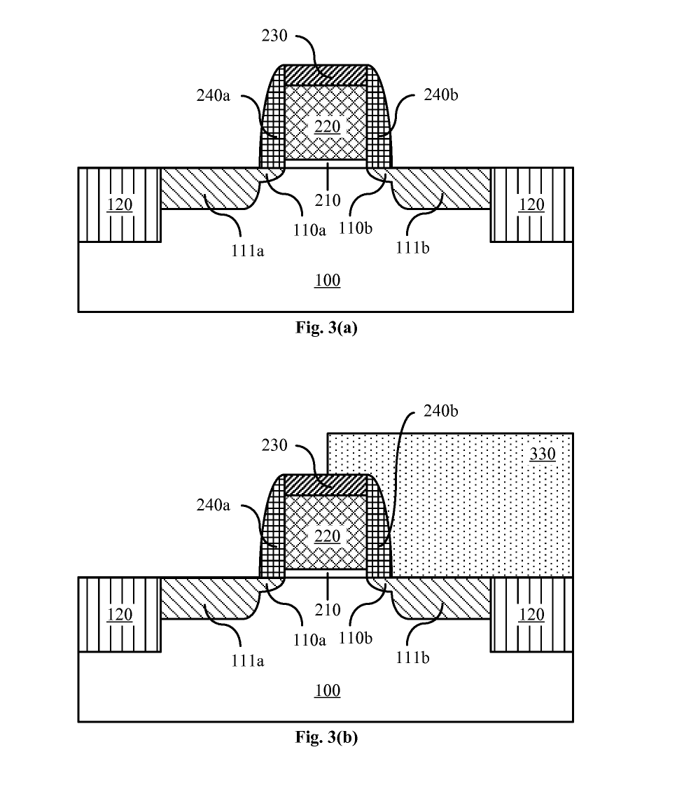

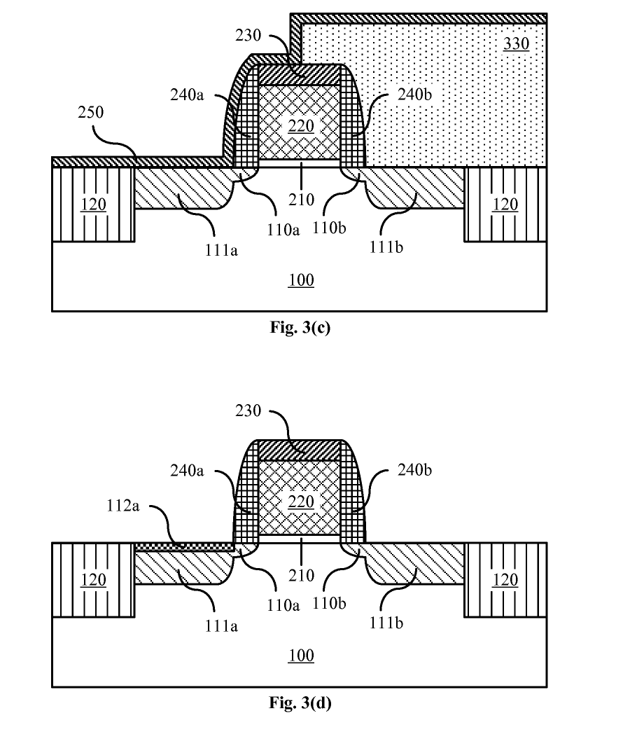

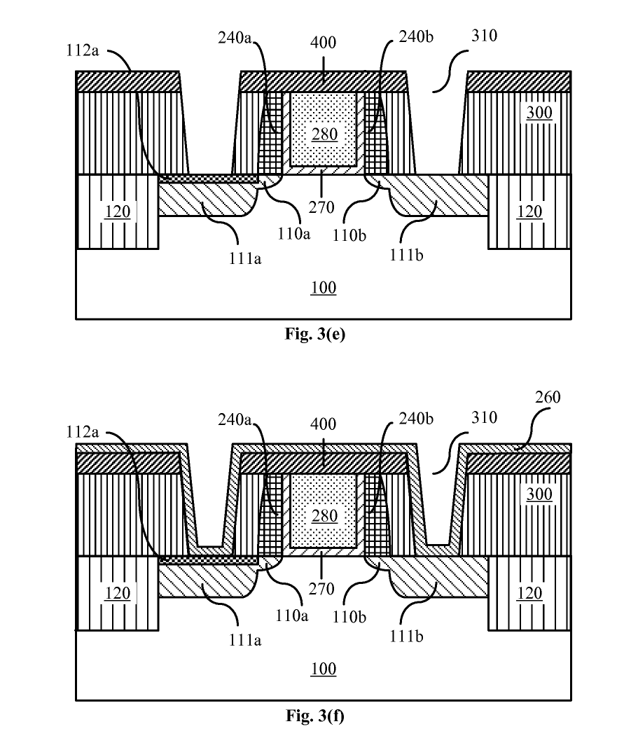

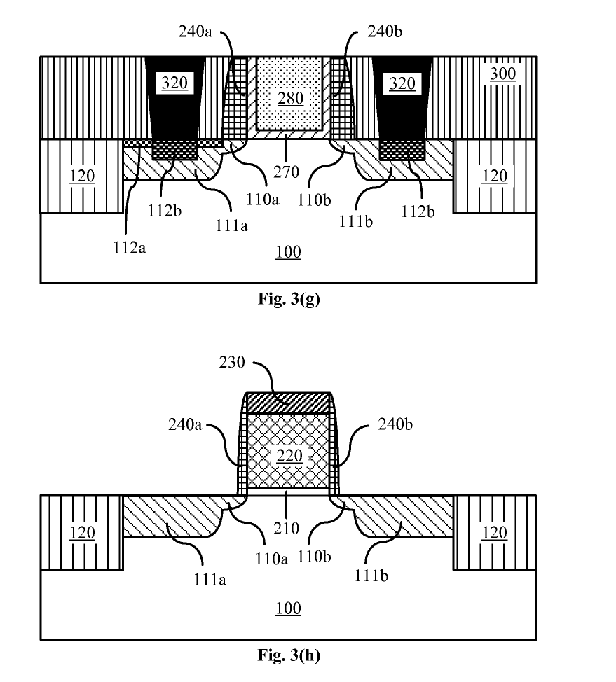

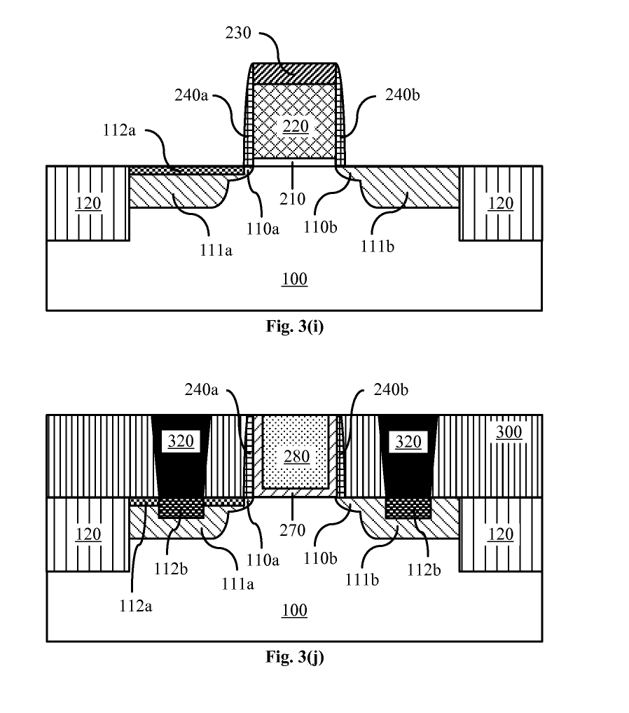

According to another aspect of the present invention, there further provides a method for manufacturing a semiconductor structure, as shown in FIG. 3. In the following, the method for forming a semiconductor structure in FIG. 3 is described in detail through one embodiment of the present invention in combination with FIGS. 3(a) to 3(g).

Referring to FIG. 3 and FIG. 3(a), in step S301, like the former embodiment, firstly, the substrate 100 is provided, on which an active region is formed, a gate stack or a dummy gate stack is formed on the active region, a source extension region 110a and a drain extension region 110b are formed at opposite sides of the gate stack or dummy gate stack, a spacer is formed on sidewalls of the gate stack or dummy gate stack, and a source 111a and a drain 111b are formed at portions of the active region exposed by the spacer and the gate stack or dummy gate stack.

Then, referring to FIGS. 3(b) to 3(d), in step S302, a first metal silicide layer 112a (that is, a first contact layer) is formed on an upper surface of a portion of the active region at the side of the source-side portion 240a of the spacer. Specifically, as shown in FIG. 3(b), the active region at the side of the drain-side portion 240b of the spacer, that is the drain 111b, is covered by a protection layer 330 (which may be a hard mask layer). Then, as shown in FIG. 3(c), a first metal layer 250 is deposited to cover the active region at the side of the source-side portion 240a of the spacer, that is the source 111a. Next, as shown in FIG. 3(d), the annealing operation is performed so that the first metal layer 250 is reacted with the source 111a at the side of the source-side portion 240a of the spacer, to form the first metal silicide layer 112a. The components and thickness of the first metal layer 250 and the first metal silicide layer 112a are the same as those in the metal layer 250 and the metal silicide layer 112 in the former embodiment, so it is unnecessary to give more details.

After the above step is completed, a metal silicide layer 112a is formed only on the upper surface of the source 111a, while no metal silicide layer is formed on the drain 111b or the drain extension region 110b.

Next, referring to FIG. 3(e), a contact hole 310 is firstly formed over the source 111a and the drain 111b. As shown in FIG. 3(e), in step S303, an interlayer dielectric layer 300 is deposited to cover the semiconductor structure. Then, the replacement gate process is performed to form a high K gate dielectric layer 270. After annealing, by depositing one of conductive materials such as one or more materials selected from a group consisting of TaC, TiN, TaTbN, TaErN, TaYbN, TaSiN, HfSiN, MoSiN, RuTaₓ, and NiTaₓ (for the NMOS device) (for the PMOS device, the conductive material may be one or more materials selected from a group consisting of MoNₓ, TiSiN, TiCN, TaAlC, TiAlN, TaN, PtSiₓ, Ni₃Si, Pt, Ru, Ir, Mo, HfRu, and RuOₓ) on the high K gate dielectric layer 270, the metal gate 280 is formed, wherein both the high K gate dielectric layer 270 and the metal gate 280 can have a multi-layer structure. Before the formation of the contact hole, a top layer 400 is formed above the interlayer dielectric layer 300 and the metal gate 280, and a material of the top layer 400 may be SiN, silicon oxide and compounds thereof, for protecting the metal gate 280 from being damaged in the subsequent process. Next, in step S304, the interlayer dielectric layer 300 is etched to expose the source 111a and the drain 111b, so as to form the contact hole 310.

Referring to FIG. 3(f), a second metal layer 260 is deposited in the contact hole 310, wherein a material of the second metal layer 260 comprises one or more materials selected from a group consisting of Ni and NiPt, with a thickness range of about 10 nm-25 nm.

Referring to FIG. 3(g), in step S305, the annealing operation is performed such that the second metal layer 260 is reacted with the source 111a and the drain 111b, to form a second metal silicide layer 112b (that is, a second contact layer), wherein a material of the second metal silicide layer 112b is NiSi or Ni(Pt)Si_{2-y}, with the preferable thickness range of about 15 nm-35 nm, thicker than the first metal silicide layer 112a, which can further reduce the contact resistance of the source 111a, while can make the first contact layer closer to the gate stack than the second contact layer under the precondition that the source-side portion and the drain-side portion of the spacer have the same thickness, so as to possibly make the second contact layer be away from the gate stack farther, which is beneficial to the reduction of the parasitic capacitance between the drain extension region and the gate. Next, the second metal layer 260 that is un-reacted is removed. Finally, a contact metal (such as a metal or an alloy of W, Cu, TiAl, Al or the like) is filled in the contact hole 310, to form a contact plug 320. In other embodiments, before the second contact layer is formed, the contact hole 310 can also only expose part of the active region at the drain side, whereas after the second contact layer is formed, the contact hole 310 for exposing part of the active region at the source side is formed.

Preferably, referring to FIG. 3(h), the processes including wet etching and/or dry etching can be used to symmetrically remove part or all of the source-side portion 240a and the drain-side portion 240b of the spacer, that is, the etched source-side portion 240a and the drain-side portion 240b of the spacer have the substantially same thickness, so as to symmetrically expose part or all of the source extension region 110a and the drain extension region 110b below the source-side portion 240a and the drain-side portion 240b of the spacer. In the gate last process, if the dummy gate 220 adopts a material that will not react with the deposited metal layer and it is possible to selectively remove the metal layer, it is possible to remove all of the source-side portion 240a and the drain-side portion 240b of the spacer, so as to enlarge the region where the source extension region 110a reacts with the deposited metal to the greatest extent. Next, the method same as that in the above is adopted, as shown in FIG. 3(i), a first metal silicide layer 112a is formed on the active region at the side of the source-side portion 240a of the spacer, that is, the source 111a and an exposed region of at least a part of the source extension region 110a, and a second metal silicide layer 112b is formed between the source 111a and the drain 111b and the contact plug 320 or between the drain 111b and the contact plug 320, as shown in FIG. 3(j).

After the above step is completed, in the semiconductor structure, the first metal silicide layer 112a is provided on an upper surface of the source 111a, or upper surfaces of the source 111a and at least a part of the source extension region 110a, which can reduce the contact resistance of the source 111a or reduce the contact resistance of the source 111a and the source extension region 112a at the same time. A second metal silicide layer 112b is formed between the source 111a and the drain 111b and the contact plug 320, wherein the second metal silicide layer 112b between the source 111a and the contact plug 320 can further reduce the contact resistance of the source 111a, and a distance between the second metal silicide layer 112b (that is between the drain 111b and the contact plug 320) and the gate stack is larger than a distance between the first metal silicide layer 112a and the gate stack, so as to reduce the parasitic capacitance between the gate stack and the drain extension region 110b and be beneficial to the improvement of the performance of the semiconductor structure. In addition, when the first metal silicide layer 112 comprises one or more materials selected from a group consisting of CoSi₂, NiSi and Ni(Pt)Si_{2-y} and has a thickness less than 10 nm, the metal silicide layer 112 can still have thermal stability and maintain relatively low resistance at an annealing temperature (for example, 700° C.-800° C.) at which the dummy gate stack is removed and the gate stack is formed subsequently.

Correspondingly, according to the method for manufacturing a semiconductor structure, the present invention further provides a semiconductor structure that is explained below according to FIG. 3(g). FIG. 3(g) shows the finally formed semiconductor structure after the steps shown in FIG. 3 are performed according to one embodiment of the present invention.

As shown in FIG. 3(g), the semiconductor structure comprises: a substrate 100, a gate stack positioned on the active region, a source 111a, a drain 111b, a source extension region 110a, a drain extension region 110b, a spacer having a source-side portion 240a and a drain-side portion 240b, and a contact plug 320, wherein the source 111a, the drain 111b, the source extension region 110a and the drain extension region 110b are formed in the substrate 100; a thickness of the source extension region 110a is less than that of the source 111a, and a thickness of the drain extension region 110b is less than that of the drain 111b.

The source-side portion 240a and the drain-side portion 240b of the spacer are positioned on sidewalls of the gate stack. A first metal silicide layer 112a is formed on an upper surface of a portion of the active region at the side of the source-side portion 240a of the spacer, that is, the first metal silicide layer 112a formed on the source 111a can reduce the contact resistance of the source. A second metal silicide layer 112b is formed between the active region not covered by the source-side portion 240a and the drain-side portion 240b of the spacer and the contact plug 320, that is, the second metal silicide layer 112b is formed between the source 111a and the drain 111b and the contact plug 320, or between the drain 111b and the contact plug 320, wherein the components and thickness of the first metal silicide layer 112a are the same as those in the former embodiment, so it is unnecessary to give more details. The second metal silicide layer 112b comprises one of NiSi and Ni(Pt)Si_{2-y}, with the preferable thickness range of about 15 nm-35 nm, which is thicker than the first metal silicide layer 112a. Since the second metal silicide layer 112b at the side of the drain-side portion 240b of the spacer may be away from the gate stack farther, it is beneficial to the reduction of the parasitic capacitance between the gate stack and the drain extension region 110b, and the second metal silicide layer 112b at the side of the source-side portion 240a of the spacer can further reduce the contact resistance of the source.

Preferably, referring to FIG. 3(j), the first metal silicide layer 112a is formed on not only the upper surface of the source 111a but also the upper surface of at least a part of the source extension region 110a, wherein the first metal silicide layer 112a positioned on the upper surface of the source extension region 110a can reduce the contact resistance of the source extension region 110a, which can further improve the performance of the semiconductor structure.

The structure compositions, materials and formation methods of each of the parts in each embodiment of the semiconductor structure can be the same as what are described in the formation method embodiment of said semiconductor structure described before, without repeated descriptions herein.

Although the exemplary embodiments and the advantages thereof are explained in detail, it is to be understood that various changes, substitutions and amendments may be made to the embodiments without departing from the spirit of the invention and the protection scopes defined in the accompanying claims. With respect to other examples, it will be easily understood by a person skilled in the art that the sequence of the processing steps may be changed while maintaining the protection scope of the present invention.

Furthermore, the application scope of the present invention is not limited to the processes, structures, manufacturing, compositions, means, methods and steps of the specific embodiments as described in the specification. According to the disclosure of the present invention, a person skilled in the art will easily appreciate that when the processes, structures, manufacturing, compositions, means, methods and steps currently existing or to be developed in future are adopted to perform functions substantially the same as corresponding embodiments described in the present invention, or achieve substantially the same effects, a person skilled in the art can make applications of them according to the present invention. Therefore, the accompanied claims of the present invention intend to include these processes, structures, manufacturing, compositions, means, methods and steps within their protection scopes.

1. A method for manufacturing a semiconductor structure, comprising:
a) providing a substrate (100), forming an active region on the substrate (100), forming a gate stack or dummy gate stack on the active region, forming a source extension region (110a) and a drain extension region (110b) at opposite sides of the gate stack or dummy gate stack, forming a spacer on sidewalls of the gate stack or dummy gate stack, and forming a source (111a) and a drain (111b) on portions of the active region exposed by the spacer and the gate stack or dummy gate stack;
b) removing at least a part of a source-side portion (240a) of the spacer, such that the source-side portion (240a) of the spacer has a thickness less than that of a drain-side portion (240b) of the spacer; and
c) forming a contact layer (112) on portions of the active region exposed by the spacer and the gate stack or dummy gate stack.

2. The method according to claim 1, wherein step b) comprises:
etching the spacer by obliquely applying a first ion beam at the source (111a) side, wherein an included angle in a clockwise direction between the first ion beam and a normal line of the substrate is larger than 0° and less than or equal to 90°.

3. The method according to claim 2, further comprising the following step before step b):
d) performing an ion implantation on the spacer by obliquely applying a second ion beam at the source (111a) side, wherein an included angle in a clockwise direction between the second ion beam and a normal line of the substrate is larger than 0° and less than or equal to 90°, and an implanted ion and a composition element of a material of the spacer are in the same clan.

4. The method according to claim 1, wherein step b) comprises:
covering the drain-side portion of the spacer (240b) by a protection layer (330);
removing at least a part of the source-side portion of the spacer (240a); and
removing the protection layer (330).

5. The method according to claim 1, wherein step c) comprises:
depositing a metal layer (250) to cover the substrate (100), the gate stack or dummy gate stack, and the spacer;
performing an annealing operation, so that the metal layer (250) reacts with the portions of the active region exposed by the spacer and the gate stack or dummy gate stack to form the contact layer (112); and
removing the metal layer (250) that is un-reacted.

6. The method according to claim 5, wherein
the metal layer (250) comprises one or more materials selected from a group consisting of Co, Ni, and NiPt.

7. The method according to claim 6, wherein
if the material of the metal layer (250) is Co, the Co layer has a thickness less than 5 nm;
if the material of the metal layer (250) is Ni, the Ni layer has a thickness less than 4 nm; or
if the material of the metal layer (250) is NiPt, the NiPt layer has a thickness less than 3 nm.

8. The method according to claim 6, wherein
if the material of the metal layer (250) is NiPt, the content of Pt in NiPt is less than 5%.

9. The method according to claim 5, wherein
the contact layer (112) comprises one or more materials selected from a group consisting of CoSi₂, NiSi, and Ni(Pt)Si_{2-y} and has a thickness less than 10 nm.

10. A semiconductor structure, comprising at least two adjacent gate stacks or dummy gate stacks positioned on an active region, source-side portions (240a) and drain-side portions (240b) of spacers, wherein
the source-side portions (240a) and the drain-side portions (240b) of the spacers are positioned on sidewalls of the gate stacks or dummy gate stacks;
for each of the gate stacks or dummy gate stacks, the source-side portion (240a) has a thickness less than that of the drain-side portion (240b) of the spacer; and
a contact layer (112) is formed on upper surfaces of portions of the active region exposed by the source-side portion (240a) and the drain-side portion (240b) as well as the gate stack or dummy gate stack.

11. The semiconductor structure according to claim 10, wherein
the contact layer (112) comprises one or more materials selected from the group consisting of CoSi₂, NiSi, and Ni(Pt)Si_{2-y} and has a thickness less than 10 nm.

12. A method for manufacturing a semiconductor structure, comprising:
a) providing a substrate (100), forming an active region on the substrate (100), forming a gate stack or dummy gate stack on the active region, forming a source extension region (110a) and a drain extension region (110b) at opposite sides of the gate stack or dummy gate stack, forming a spacer on sidewalls of the gate stack or dummy gate stack, and forming a source (111a) and a drain (111b) on portions of the active region exposed by the spacer and the gate stack or dummy gate stack;
b) forming a first contact layer (112a) on an upper surface of a portion of the active region at the source side;
c) forming an interlayer dielectric layer (300) to cover the substrate (100);
d) etching the interlayer dielectric layer (300) to form a contact hole (310) which at least exposes a part of a portion of the active region at the drain side; and
e) forming a second contact layer (112b) on the part of the portion of the active region at the drain side.

13. The method according to claim 12, further comprising the following step before step b):
f) symmetrically removing at least a part of the spacer.

14. The method according claim 12, wherein step b) comprises:
covering the portion of the active region at the drain side by a protection layer (330);
depositing a first metal layer (250) to cover the portion of the active region at the source side;
performing an annealing operation, such that the first metal layer (250) reacts with the portion of the active region at the source side to form a first contact layer (112a); and
removing the first metal layer (250) that is un-reacted.

15. The method according to claim 14, wherein
a material of the first metal layer (250) is one or more materials selected from a group consisting of Co, Ni and NiPt.

16. The method according to claim 15, wherein
if the material of the first metal layer (250) is Co, the Co layer has a thickness less than 5 nm;
if the material of the first metal layer (250) is Ni, the Ni layer has a thickness less than 4 nm; or
if the material of the first metal layer (250) is NiPt, the NiPt layer has a thickness less than 3 nm.

17. The method according to claim 15, wherein
if the material of the first metal layer (250) is NiPt, the content of Pt in NiPt is less than 5%.

18. The method according to claim 12, wherein step e) comprises:
depositing a second metal layer (260) to cover the region;
performing an annealing operation so that the second metal layer (260) reacts with the part of the active region to form the second contact layer (112b); and
removing the second metal layer (260) that is un-reacted.

19. The method according to claim 18, wherein
a material of the second metal layer (260) comprises one or more materials selected from the group consisting of Ni and NiPt.

20. The method according to claim 12, wherein
the first contact layer (112) comprises one or more materials selected from the group consisting of CoSi₂, NiSi and Ni(Pt)Si_{2-y} and has a thickness less than 10 nm.

21. The method according to claim 12, wherein
a material of the second contact layer (112b) comprises one or more materials selected from the group consisting of NiSi and Ni(Pt)Si_{2-y}.

22. A semiconductor structure, comprising a gate stack, a source (111a), a drain (111b) and a contact plug (320), wherein the gate stack is positioned on an active region, the source (111a) and the drain (111b) are respectively positioned in the active region at opposite sides of the gate stack, and the contact plug (320) is connected to the active region exposed by the gate stack, wherein
a first contact layer (112a) is formed on an upper surface of a portion of the active region at the source side; and
a second contact layer (112b) is formed at least between the portion of the active region at the drain side and the contact plug (320).

23. The semiconductor structure according to claim 22, wherein
the first contact layer (112a) comprises one or more materials selected from the group consisting of CoSi₂, NiSi and Ni(Pt)Si_{2-y} and has a thickness less than 10 nm.

24. The semiconductor structure according to claim 22, wherein
the second contact layer (112b) comprises one or more materials selected from the group consisting of NiSi and Ni(Pt)Si_{2-y}.
